(19) United States
(12) Patent Application Publication
(10) Pub. No.: US 2019/0080984 A1
(43) Pub. Date: Mar. 14, 2019

(54) LIQUID-COOLED TYPE COOLING DEVICE

(71) Applicant: KEIHIN THERMAL TECHNOLOGY CORPORATION, Oyama-shi (JP)

(72) Inventors: Naohisa Higashiyama, Oyama-shi (JP); Takashi Hirayama, Oyama-shi (JP)

(73) Assignee: KEIHIN THERMAL TECHNOLOGY CORPORATION, Oyama-shi (JP)

(21) Appl. No.: 16/128,522

(22) Filed: Sep. 12, 2018

(30) Foreign Application Priority Data
Sep. 14, 2017 (JP) 2017-177006
Jan. 26, 2018 (JP) 2018-011157

(51) Int. Cl. H01L 23/473; F28F 3/02; F28F 3/12

(52) U.S. Cl. CPC H01L 23/473; H01L 23/3675; F28F 3/12; F28F 3/027

(57) ABSTRACT

In a liquid-cooled type cooling device, fins are accommodated in the interior of a casing having a supply port and a discharge port, and electronic components that are associated with generation of heat are mounted on a top wall part of a first case unit of the casing. At end portions in a widthwise direction of the fins, cutouts are formed, which are cut out toward the side of a bottom wall part of a second case unit, in facing relation to the top wall part of the first case unit.

### CROSS-REFERENCE TO RELATED APPLICATION

This application is based upon and claims the benefit of priority from Japanese Patent Applications No. 2017-177006 filed on Sep. 14, 2017 and No. 2018-011157 filed on Jan. 26, 2018, the contents all of which are incorporated herein by reference.

### BACKGROUND OF THE INVENTION

### Field of the Invention

The present invention relates to a liquid-cooled type cooling device, which is capable of cooling electronic components by heat exchange with a coolant medium that flows through a plurality of flow paths.

### Description of the Related Art

Conventionally, for example, as disclosed in Japanese Laid-Open Patent Publication No 2016-015381, a cooling device for cooling an electronic component, for example, a semiconductor device that generates heat, is known. Such a cooling device is equipped with a base plate on which an electronic component is mounted, a cover adapted to cover an upper surface of the base plate, and fins accommodated in a space between the cover and the base plate. A supply pipe to which a coolant medium is supplied is connected to a central location in a widthwise direction of the cover, and a pair of discharge pipes from which the coolant medium is discharged are connected to central locations in the widthwise direction, in the vicinity of outer edge portions of the cover.

In addition, the coolant medium is supplied from the supply pipe to a supply-side manifold, and flows to the left and right along coolant medium flow paths of the fins to discharge-side manifolds, whereby heat exchange and cooling is carried out between the electronic component and the base plate that is joined to the fins, and the coolant medium which was subjected to heat exchange is discharged from the discharge pipes.

### SUMMARY OF THE INVENTION

In a cooling device such as the one described above, there is a requirement, while maintaining the cooling performance of the electronic component, to further reduce a pressure loss that takes place when the coolant medium, which is supplied from the supply pipe, flows along the fins toward the discharge pipes.

A general object of the present invention is to provide a liquid-cooled type cooling device, which is capable of further reducing a pressure loss while maintaining the cooling performance with respect to electronic components.

The present invention is characterized by a liquid-cooled type cooling device adapted to cool an electronic component disposed on a casing and associated with generation of heat, by heat exchange with a coolant medium, comprising the casing having a supply passage to which the coolant medium is supplied and a discharge passage from which the coolant medium is discharged, and fins accommodated inside the casing, wherein:

in the casing, there are included a first wall part on which the electronic component is mounted, and a second wall part facing toward the first wall part with the fins interposed therebetween, and an opening of the supply passage and an opening of the discharge passage open in the same direction or in opposite directions, and in directions substantially parallel to the first and second wall parts; and

the fins include cutouts on the side of the second wall part, the cutouts being formed in one end of the fins on at least one side of the supply passage and the discharge passage.

According to the present invention, the casing constituting the liquid-cooled type cooling device includes the first wall part on which the electronic component is mounted, and the second wall part facing toward the first wall part with the fins interposed therebetween. Further, on the fins that are accommodated inside the casing, the cutouts are formed on the side of the second wall part, in one end of the fins on at least one side of the supply passage and the discharge passage.

Accordingly, since the passage cross-sectional area of at least one of the supply passage and the discharge passage can be increased by the cutouts, it is possible to suitably reduce any pressure loss when the coolant medium flows through the supply passage and the discharge passage. Further, by providing the cutouts on the side of the second wall part which is arranged so as to face toward the first wall part on which the electronic components are mounted, the cooling performance is suitably maintained, without any decrease in the contact area between the first wall part and the fins, or any deterioration in the cooling performance with respect to the electronic components. As a result, in a liquid-cooled type cooling device, it is possible to reduce pressure loss while maintaining the cooling performance of the electronic components.

The above and other objects, features, and advantages of the present invention will become more apparent from the following description when taken in conjunction with the accompanying drawings, in which preferred embodiments of the present invention are shown by way of illustrative example.

### BRIEF DESCRIPTION OF THE DRAWINGS

FIG. 1 is an external perspective view of a liquid-cooled type cooling device according to a first embodiment of the present invention;

FIG. 2 is a plan cross-sectional view of the liquid-cooled type cooling device shown in FIG. 1;

FIG. 3 is a cross-sectional view taken along line III-III of FIG. 2;

FIG. 4A is a cross-sectional view of a liquid-cooled type cooling device according to a first modification;

FIG. 4B is a cross-sectional view of a liquid-cooled type cooling device according to a second modification;

FIG. 5A is a plan cross-sectional view of a liquid-cooled type cooling device according to a second embodiment of the present invention;

FIG. 5B is a cross-sectional view taken along line VB-VB of FIG. 5A;

FIG. 6A is a plan cross-sectional view of a liquid-cooled type cooling device according to a third embodiment of the present invention; and

FIG. 6B is a cross-sectional view taken along line VIB-VIB of FIG. 6A.

### DESCRIPTION OF THE PREFERRED EMBODIMENTS

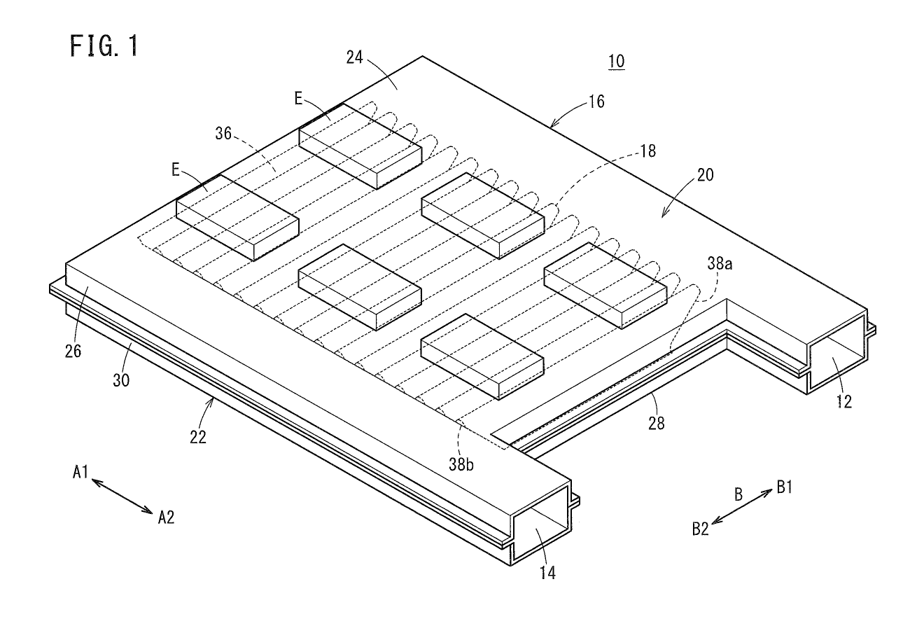

As shown in FIGS. 1 to 3, the liquid-cooled type cooling device 10 includes a casing 16 having a supply port (opening) 12 to which a coolant medium is supplied, and a discharge port (opening) 14 through which the coolant medium is discharged, and fins 18 that are accommodated in the interior of the casing 16.

The casing 16 is made up from first and second case units 20, 22 which are capable of being divided in a vertical direction. The first case unit 20 is constituted from a flat top wall part (first wall part) 24 and a first side wall part 26 erected on an outer edge of the top wall part 24, and a plurality of electronic components E made of semiconductors or the like which are required to be cooled and are mounted on an upper surface of the top wall part 24.

The electronic components E are disposed in a mutually spaced apart manner at predetermined intervals along a longitudinal direction (the direction of arrows A1, A2) of a supply passage 32 and a discharge passage 34 of the casing 16, together with being arranged in parallel with each other along coolant medium flow paths 36, so as to be separated away from each other in the widthwise direction (the direction of arrow B) of the casing 16. Herein, a situation will be described in which a total of six electronic components E are installed on the casing 16.

The second case unit 22 is constituted from a flat bottom wall part (second wall part) 28 and a second side wall part 30 erected on an outer edge portion of the bottom wall part 28. The bottom wall part 28 is formed in substantially the same shape as the top wall part 24 of the first case unit 20, and together therewith, an end of the second side wall part 30 is placed in contact with and connected by brazing or the like to an end of the first side wall part 26 on the first case unit 20. More specifically, the top wall part 24 of the first case unit 20 and the bottom wall part 28 of the second case unit 22 are separated by a predetermined distance, and are disposed substantially in parallel.

On one end portion of the casing 16, the supply port 12 and the discharge port 14 open in the same direction, and the supply port 12 and the discharge port 14 are arranged with a predetermined interval of separation therebetween along the widthwise direction (the direction of arrow B).

The supply port 12 is connected, for example, to a supply pipe (not shown) to which a coolant medium is supplied from a non-illustrated pump, and communicates with a supply passage 32 extending along the longitudinal direction (the direction of arrows A1, A2). On the other hand, the discharge port 14 is connected, for example, to a discharge pipe (not shown) through which a coolant medium is discharged, and communicates with a discharge passage 34 extending along the longitudinal direction (the direction of arrows A1, A2), together with being disposed in parallel with the supply passage 32.

Further, the supply passage 32 including the supply port 12, and the discharge passage 34 including the discharge port 14 are formed with the same passage cross-sectional area.

The fins 18 are provided between the supply passage 32 and the discharge passage 34. The fins 18 are formed, for example, so as to be bent with a wave-like shape in cross section as viewed from the widthwise direction (the direction of the arrow B). The fins 18 extend in such a wave-like shape along the direction in which the supply passage 32 and the discharge passage 34 extend, and together therewith, crest portions thereof are brought respectively into contact with the top wall part 24 and the bottom wall part 28 of the casing 16, and are connected thereto by brazing. Additionally, the fins 18 serve as a plurality of coolant medium flow paths 36 that extend substantially horizontally along the widthwise direction (the direction of arrow B) of the casing 16.

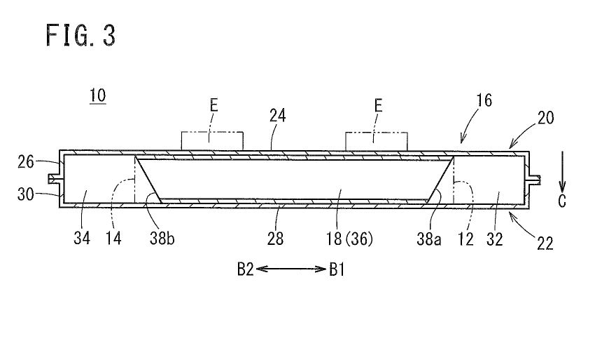

Further, as shown in FIG. 3, at ends of the fins 18 in the widthwise direction, on the side of the bottom wall part 28 (in the direction of the arrow C) of the casing 16, as viewed from the direction in which the supply passage 32 and the discharge passage 34 extend, cutouts 38a, 38b are formed, respectively. The cutouts 38a, 38b are cut out with triangular shapes in cross section, having a gradually widening width in a downward direction (the direction of the arrow C) toward the side of the bottom wall part 28 from the upper portion of the casing 16 on the side of the top wall part 24.

Stated otherwise, the cutouts 38a, 38b are cut out in a manner so as to be inclined gradually in a downward direction toward the side of the bottom wall part 28, at a predetermined angle toward the center in the widthwise direction of the fins 18.

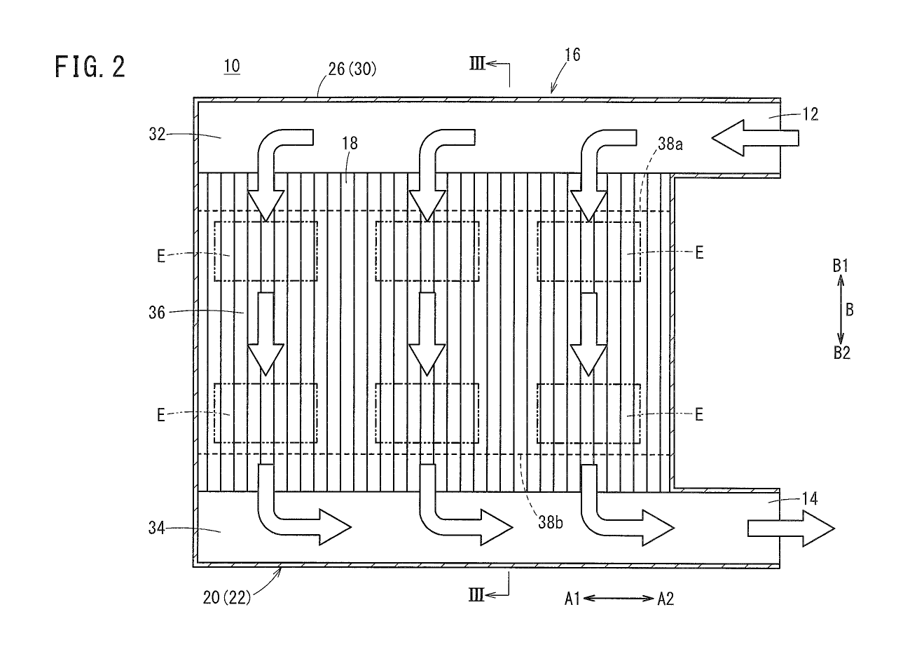

More specifically, as shown in FIGS. 2 and 3, the cutouts 38a, 38b are formed respectively at both end portions of the fins 18 on the sides of the supply passage 32 and the discharge passage 34 (in the directions of arrows B1 and B2).

The liquid-cooled type cooling device 10 according to the first embodiment of the present invention is basically constructed in the manner described above. Next, operations and effects of the liquid-cooled type cooling device 10 will be described.

The coolant medium is supplied through a supply pipe from a non-illustrated coolant medium supply means such as a pump or the like to the supply port 12, and the coolant medium flows through the supply passage 32 toward a rear side of the casing 16 (in the direction of the arrow A1). At this time, since the cutouts 38a are provided at ends of the fins 18 facing toward the supply passage 32, the cross-sectional area of the cutouts 38a is added to the passage cross-sectional area of the supply passage 32, and the coolant medium flows along the supply passage 32 having an enlarged passage cross-sectional area. More specifically, since the passage cross-sectional area is increased as compared to a case in which the cutouts 38a are not provided, a pressure loss when the coolant medium flows through the supply passage 32 is reduced.

In addition, the coolant medium, which has flowed in from the supply passage 32 to the plurality of coolant medium flow paths 36 in the fins 18, flows to the side of the discharge passage 34 (in the direction of the arrow B2), and simultaneously therewith, heat exchange takes place via the fins 18 and the casing 16 between the coolant medium and the heat generated by the electronic components E, which are arranged on the top wall part 24, so as to face toward the fins 18. Consequently, the electronic components E are cooled together with the coolant medium being heated.

Finally, the coolant medium that was subjected to heat exchange flows respectively from each of the coolant medium flow paths 36 into the discharge passage 34, and is discharged from the discharge port 14 into a non-illustrated discharge pipe. In the discharge passage 34 as well, since the cutouts 38b are provided at ends in the widthwise direction of the fins 18 facing toward the discharge passage 34, the cross-sectional area of the cutouts 38b is added to the passage cross-sectional area of the discharge passage 34, and the coolant medium flows along the discharge passage 34 having an enlarged passage cross-sectional area toward the downstream side (in the direction of the arrow A2). Moreover, the coolant medium is cooled again externally of the liquid-cooled type cooling device 10, and thereafter, is supplied and recirculated from the coolant medium supply means to the supply passage 32.

In the foregoing manner, according to the first embodiment, the cutouts 38a, 38b, which are cut out with triangular shapes in cross section, are formed in the fins 18 that are accommodated in the interior of the casing 16, at ends thereof in the widthwise direction on the sides of the supply passage 32 and the discharge passage 34. Consequently, since the passage cross-sectional area of the supply passage 32 and the discharge passage 34 can be increased by the cutouts 38a, 38b, it is possible to suitably reduce any pressure loss when the coolant medium flows through the supply passage 32 and the discharge passage 34.

Further, by providing the cutouts 38a, 38b on the side of the second case unit 22 (in the direction of the arrow C) where the electronic components E are not mounted on the casing 16, even in the case of providing the cutouts 38a, 38b, there is no reduction in the contact area between the first case unit 20 and the fins 18, and the cooling performance with respect to the electronic components E is prevented from deteriorating. As a result, in the liquid-cooled type cooling device 10, it is possible to reduce pressure loss while maintaining the cooling performance of the electronic components E.

Furthermore, by reducing the pressure loss of the coolant medium that flows inside the casing 16, it is possible to make the passage cross-sectional area of the supply passage 32 and the discharge passage 34 smaller, and to minimize the size of the liquid-cooled type cooling device 10 including the casing 16.

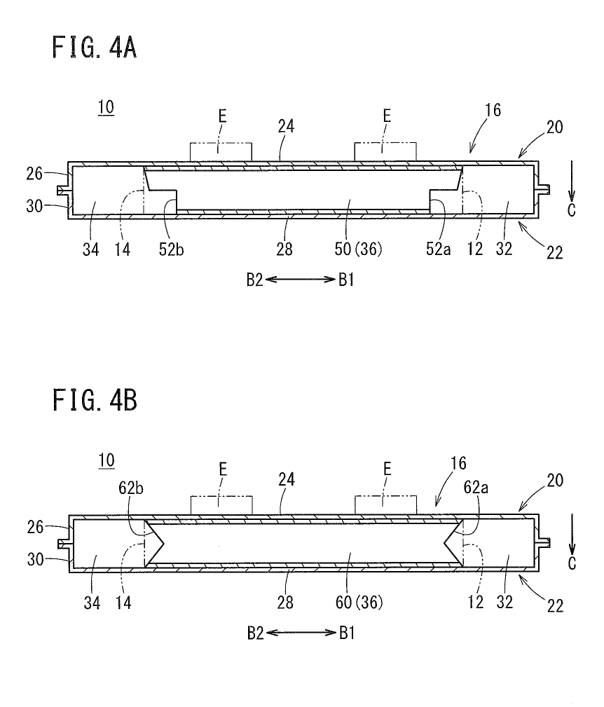

On the other hand, the present invention is not limited to the above-described case, in which the cutouts 38a, 38b, which are formed at both ends of the fins 18, are formed with triangular shapes in cross section, with the width of the cutouts 38a, 38b gradually increasing toward the side of the bottom wall part 28 (in the direction of the arrow C). For example, as in the case of the fins 50 shown in FIG. 4A, cutouts 52a, 52b may be formed in which lower portions thereof on the side of the bottom wall part 28 (in the direction of the arrow C) are cut out with rectangular shapes in cross section in directions toward the center in the widthwise direction. In addition, as in the case of the fins 60 shown in FIG. 4B, cutouts 62a, 62b may be formed with V-shapes in cross section, in which intermediate portions thereof on the sides of the bottom wall part 28 and the top wall part 24 are cut out toward the center in the widthwise direction.

The cutouts 62a, 62b having such V-shaped cross sections are disposed in the casing 16 at a predetermined distance from both the top wall part 24 of the first case unit 20 and the bottom wall part 28 of the second case unit 22, and therefore, even in the case that the electronic components E are mounted, respectively, on the top wall part 24 and the bottom wall part 28, the cooling performance thereof is not degraded, and the electronic components E can be suitably cooled.

More specifically, the cutouts 38a, 38b, 52a, 52b, and 62a, 62b may be provided in the fins 18, 50, 60 in any portions thereof, excluding the portion on the side of the top wall part 24 of the first case unit 20 on which the electronic components E are mounted, and the shape of the cutouts is not particularly limited.

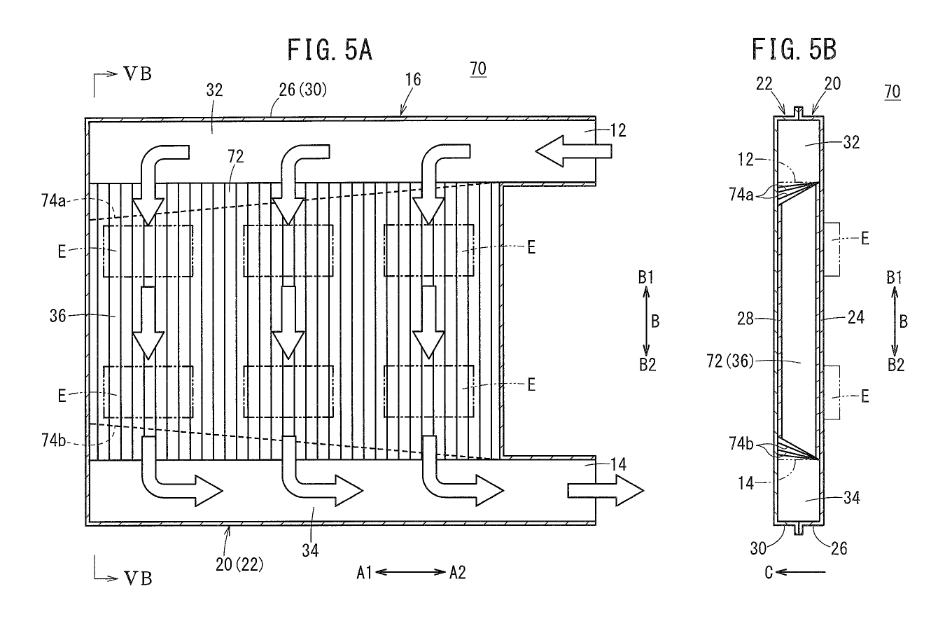

Next, a liquid-cooled type cooling device 70 according to a second embodiment is shown in FIGS. 5A and 5B. The same constituent elements as those of the liquid-cooled type cooling device 10 according to the above-described first embodiment are denoted using the same reference numerals, and detailed description of such features is omitted.

The liquid-cooled type cooling device 70 according to the second embodiment differs from the liquid-cooled type cooling device 10 according to the first embodiment, in that cutouts 74a, 74b at ends in the widthwise direction of the fins 72 are formed to gradually increase toward a rear side (in the direction of the arrow A1) along the longitudinal direction of the supply passage 32 and the discharge passage 34.

As shown in FIGS. 5A and 5B, in the liquid-cooled type cooling device 70, the cutouts 74a, 74b, which are formed respectively on ends in the widthwise direction of the fins 72, are formed in a manner so that the cross-sectional area thereof becomes gradually larger from a front side toward a rear side (in the direction of the arrow A1) of the supply passage 32 and the discharge passage 34, along the longitudinal direction on sides of the supply port 12 and the discharge port 14.

More specifically, as shown in FIG. 5B, the angle of inclination is formed to increase, in a manner so that lower end portions of the cutouts 74a, 74b on the side of the second case unit 22 gradually move toward the inner side in the widthwise direction of the fins 72.

Stated otherwise, the supply passage 32 and the discharge passage 34 are formed in a manner so that the passage cross-sectional area thereof becomes gradually larger from the front side (in the direction of the arrow A2) toward the rear side (in the direction of the arrow A1) on the sides of the supply port 12 and the discharge port 14.

In addition, when the coolant medium supplied from the coolant medium supply means into the supply port 12 flows along the supply passage 32 toward the rear side (in the direction of the arrow A1) of the casing 16, generally, flowing of the coolant medium from the supply passage 32 to the plurality of the coolant medium flow paths 36 flows easily into the coolant medium flow paths 36 on the front side (in the direction of the arrow A2) in the supply passage 32, yet it becomes gradually more difficult for the coolant medium to flow into the coolant medium flow paths 36 toward the rear side (in the direction of the arrow A1).

In contrast thereto, since the passage cross-sectional area is formed so as to gradually increased toward the rear side of the supply passage 32 due to the cutouts 74a provided in the fins 72, the difficulty in flowing of the coolant medium into the coolant medium flow paths 36 on the rear side of the supply passage 32 can be eliminated, and it is possible to cause the coolant medium to flow in a uniform manner through the coolant medium flow paths 36 along the longitudinal direction of the supply passage 32.

The coolant medium that has flowed into the plurality of coolant medium flow paths 36 flows respectively therein toward the side of the discharge passage 34 (in the direction of the arrow B2), and by flowing through the coolant medium flow paths 36, the plurality of electronic components E are cooled respectively in a substantially uniform manner. Together therewith, the coolant medium that has flowed into the discharge passage 34 flows to the side of the discharge port 14 through the discharge passage 34, in which the passage cross-sectional area thereof is increased by the cutouts 74b, which are cut out in a manner so that the cross-sectional area thereof gradually increases toward the rear side of the discharge passage 34. Thereafter, the coolant medium flows into an unillustrated discharge pipe.

In the foregoing manner, according to the second embodiment, in the fins 72 that are accommodated in the casing 16, the cutouts 74a, 74b are formed in a manner so that the cross-sectional area thereof becomes gradually larger from the front side toward the rear side (in the direction of the arrow A1) of the supply passage 32 and the discharge passage 34. Consequently, the coolant medium that flows from the supply passage 32 into the coolant medium flow paths 36 of the fins 72 can be made to flow substantially uniformly along the longitudinal direction of the supply passage 32, and therefore, the plurality of electronic components E that are mounted on the casing 16 can be cooled in a substantially uniform manner, and the cooling efficiency thereof can be enhanced.

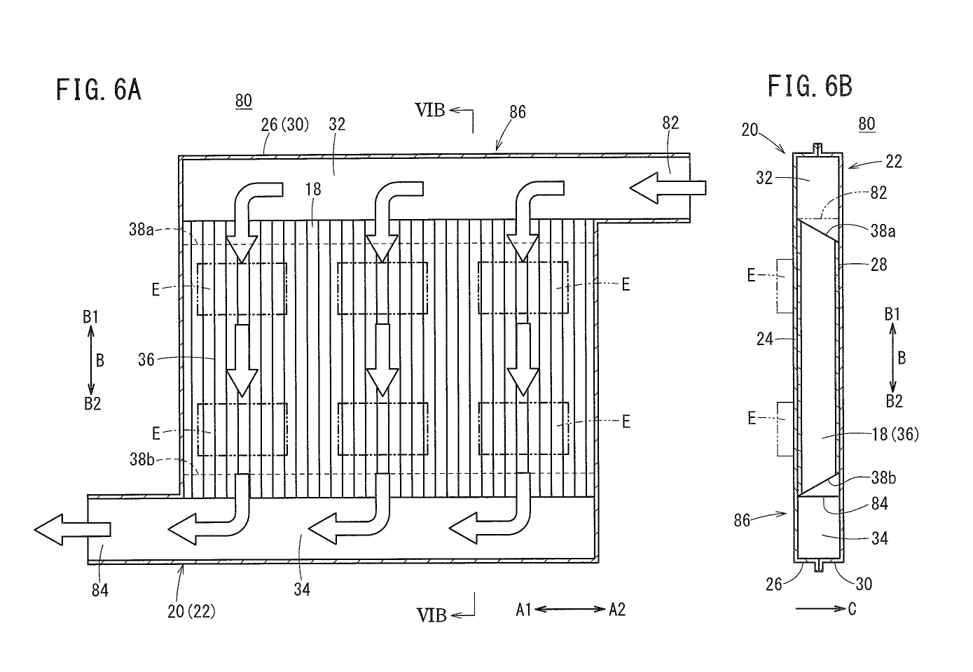

Next, a liquid-cooled type cooling device 80 according to a third embodiment is shown in FIGS. 6A and 6B. The same constituent elements as those of the liquid-cooled type cooling devices 10, 70 according to the above-described first and second embodiments are denoted using the same reference numerals, and detailed description of such features is omitted.

The liquid-cooled type cooling device 80 according to the third embodiment differs from the liquid-cooled type cooling devices 10, 70 according to the first and second embodiments, in that the supply port 82 and the discharge port 84 open in mutually opposite directions to one another in the longitudinal direction (the direction of arrows A1, A2) of the casing 86.

As shown in FIGS. 6A and 6B, in the liquid-cooled type cooling device 80, in the casing 86, the supply port 82 opens on one end side (front side, in the direction of the arrow A2) of the supply passage 32, whereas the discharge port 84 opens on another end side (rear side, in the direction of the arrow A1) of the discharge passage 34.

In addition, the coolant medium, which is supplied from a non-illustrated coolant medium supply means such as a pump or the like into the supply port 82 that opens on the front side, flows through the supply passage 32 toward the rear side of the casing 86 (in the direction of the arrow A1). At this time, since the cutouts 38a are provided at ends in the widthwise direction of the fins 18, the coolant medium flows along the supply passage 32 having a passage cross-sectional area in which the cutouts 38a are added to the supply passage 32, and any pressure loss when the coolant medium flows through the supply passage 32 is reduced.

The coolant medium flows in from the supply passage 32 and into the plurality of coolant medium flow paths 36 of the fins 18, and flows respectively therein toward the side of the discharge passage 34 (in the direction of the arrow B2). Simultaneously therewith, heat exchange takes place via the fins 18 and the casing 86 between the coolant medium and the heat generated by the electronic components E, which are arranged on the top wall part 24. Consequently, simultaneously with the electronic components E being cooled, the coolant medium is heated.

Finally, the coolant medium that was subjected to heat exchange flows respectively from each of the coolant medium flow paths 36 into the discharge passage 34, and after having flowed to the other end side (rear side, in the direction of the arrow A1) along the discharge passage 34 in the same direction as the flow of the supply passage 32, the coolant medium is discharged into a non-illustrated discharge pipe from the discharge port 84 which opens on the other end of the casing 86.

In the discharge passage 34 as well, since the cutouts 38b are provided at ends in the widthwise direction of the fins 18 facing toward the discharge passage 34, the coolant medium flows along the discharge passage 34, the passage cross-sectional area of which is enlarged due to the cutouts 38b, toward the downstream side (in the direction of the arrow A1). Moreover, the coolant medium is cooled again externally of the liquid-cooled type cooling device 80, and thereafter, is supplied and recirculated from the coolant medium supply means to the supply passage 32.

More specifically, in the liquid-cooled type cooling device 80, the flow direction of the coolant medium flowing through the supply passage 32, and the flow direction of the coolant medium flowing through the discharge passage 34 are in the same direction (the direction of the arrow A1).

In the foregoing manner, according to the third embodiment, in the liquid-cooled type cooling device 80, in which the supply port 82 and the discharge port 84 open on opposite sides in the longitudinal direction (the direction of arrows A1 and A2) of the casing 86, the cutouts 38a, 38b are provided, which are cut out with triangular shapes in cross section on ends in the widthwise direction of the fins 18 that are accommodated in the interior of the casing 86. Consequently, since the passage cross-sectional area of the supply passage 32 and the discharge passage 34 can be increased by the cutouts 38a, 38b, it is possible to suitably reduce any pressure loss when the coolant medium flows through the supply passage 32 and the discharge passage 34.

The liquid-cooled type cooling device according to the present invention is not limited to the above-described embodiments, and it goes without saying that various modified or additional configurations could be adopted therein without departing from the essence and gist of the present invention.

What is claimed is:

1. A liquid-cooled type cooling device adapted to cool an electronic component disposed on a casing and associated with generation of heat, by heat exchange with a coolant medium, comprising the casing having a supply passage to which the coolant medium is supplied and a discharge passage from which the coolant medium is discharged, and fins accommodated inside the casing, wherein:
in the casing, there are included a first wall part on which the electronic component is mounted, and a second wall part facing toward the first wall part with the fins interposed between the first wall part and the second wall part, and an opening of the supply passage and an opening of the discharge passage open in a same direction or in opposite directions, and in directions substantially parallel to the first wall part and the second wall part; and
the fins include cutouts on the side of the second wall part, the cutouts being formed in one end of the fins on at least one side of the supply passage and the discharge passage.

2. The liquid-cooled type cooling device according to claim 1, wherein the cutouts are formed in a manner so that a cross-sectional area thereof gradually increases in a direction away from the opening of the supply passage and the opening of the discharge passage.

3. The liquid-cooled type cooling device according to claim 1, wherein the cutouts are formed with triangular shapes in cross section, having a gradually wider shape in a direction toward the second wall part.

4. The liquid-cooled type cooling device according to claim 1, wherein the cutouts are formed with V-shapes in cross section away from the first wall part and the second wall part, and recessed along a direction in which the fins extend.

5. The liquid-cooled type cooling device according to claim 1, wherein a flow direction of the coolant medium flowing through the supply passage, and a flow direction of the coolant medium flowing through the discharge passage are in a same direction or in opposite directions.
